(19) United States
(12) Patent Application Publication
(10) Pub. No.: US 2023/0060680 A1
(43) Pub. Date: Mar. 2, 2023

(54) MATERIALS EXHIBITING TRANSPORT PROPERTIES SPECIFIC TO WEYL FERMIONS AND MAGNETRESISTANCE DEVICES BASED ON SUCH MATERIALS

(71) Applicant: Nippon Telegraph and Telephone Corporation, Tokyo (JP)

(72) Inventors: Yuki Wakabayashi, Tokyo (JP); Yoshiharu Krockenberger, Tokyo (JP); Hiroshi Irie, Tokyo (JP); Yoshitaka Taniyasu, Tokyo (JP); Hideki Yamamoto, Tokyo (JP)

(21) Appl. No.: 17/800,323

(22) PCT Filed: Mar. 26, 2020
(86) PCT No.: PCT/JP2020/013561

§ 371 Date: Aug. 17, 2022

(51) Int. Cl. H01L 43/10; H01L 43/06; H01L 43/14; H01F 10/32

(52) U.S. Cl. CPC H01L 43/10; H01F 10/3254; H01L 43/14; H01L 43/065

(57) ABSTRACT

A material exhibiting transport phenomena of Weyl fermions is composed of SrRuO₃ and has a ratio of a resistivity p at 300 K to a resistivity p at 4 K [residual resistivity ratio RRR=ρ(300 K)/ρ(4 K)] of 20 or greater.

### CROSS-REFERENCE TO RELATED APPLICATIONS

This application is a national phase entry of PCT Application No. PCT/JP2020/013561, filed on Mar. 26, 2020, which application is hereby incorporated herein by reference.

### TECHNICAL FIELD

The present invention relates to a material exhibiting transport phenomena of Weyl fermions and a magnetoresistive element.

### BACKGROUND

SrRuO₃ (in perovskite structure) is a ferromagnetic metal having a maximum Curie temperature (T_{c}) of 160 K. SrRuO₃ has high chemical stability and high electrical conductivity, and is highly consistent with perovskite oxides such as SrTiO₃. Due to these features, SrRuO₃ is a promising material for electronics applications such as MOSFETs and LEDs using oxides (Non-Patent Literature 1).

Furthermore, SrRuO₃ is a material that exhibits a tunnel magnetoresistance effect (Non-Patent Literature 2) and that is capable of controlling magnetization direction with current by utilizing spin transfer torque (Non-Patent Literature 3). Therefore, SrRuO₃ is a promising material also for spin electronics applications such as magnetoresistive memories (MRAMs) and spin MOSFETs (Non-Patent Literature 4). However, the maximum magnetoresistivity ratio of SrRuO₃ ever observed is 65% (Non-Patent Literature 5), and thus SrRuO₃ has been problematic in that the magnetic field detection sensitivity is small for use as a magnetic sensor.

A Weyl fermion that is massless and has linear band dispersion in a material is known (Non-Patent Literature 6). The Weyl fermion has high mobility as transport properties in a material. Therefore, the Weyl fermion is expected to be applied to devices such as transistors operating at high speed and in low power consumption. Furthermore, the Weyl fermion is promising also for applications to highly-sensitive magnetic field sensors using a huge positive magnetoresistance effect derived therefrom and chiral-anomaly-induced magnetoresistance, which is a large negative magnetoresistance effect.

### Citation List

### Non-Patent Literature

Non-Patent Literature 1: H. Y. Hwang et al., “Emergent phenomena at oxide interfaces”, Nature Materials, vol. 11, pp. 103-113, 2012.

Non-Patent Literature 2: D. C. Worledge and T. H. Geballe, “Negative Spin-Polarization of SrRuO₃”, PHYSICAL Review Letters, vol. 85, no. Negative Spin-Polarization of SrRuO₃, pp. 5182-5185, 2000.

Non-Patent Literature 3: L. Liu et al., “Current-induced magnetization switching in all-oxide heterostructures”, Nature Nanotechnology, vol. 14, pp. 939-944, 2019.

Non-Patent Literature 4: S. Sugahara and M. Tanaka, “A spin metal-oxide-semiconductor field-effect transistor using half-metallic-ferromagnet contacts for the source and drain”, Applied Physics Letters, vol. 84, no. 13, pp. 2307-2309, 2004.

Non-Patent Literature 5: A. P. Mackenzie et al., “Observation of quantum oscillations in the electrical resistivity of SrRuO₃”, Physical Review B, vol. 58, no. 20, R13318, 1998.

Non-Patent Literature 6: X. Huang et al., “Observation of the Chiral-Anomaly-Induced Negative Magnetoresistance in 3D Weyl Semimetal TaAs”, Physical Review X, vol. 5, no. 3, 031023, 2015.

Non-Patent Literature 7: Y. Chen et al., “Weyl fermions and the anomalous Hall effect in metallic ferromagnets”, Physical Review B, vol. 88, no. 12, 125110, 2013.

### SUMMARY

### Technical Problem

The presence of Weyl fermions in SrRuO₃ is theoretically predicted (Non-Patent Literature 7). However, SrRuO₃ that exhibits transport phenomena of Weyl fermions has not been obtained in which Weyl fermions are transported and which has high mobility, a huge positive magnetoresistance effect, and large chiral-anomaly-induced negative magnetoresistance.

Embodiments of the present invention have been made to solve the above-mentioned problem, and it is an object of embodiments of the present invention to obtain SrRuO₃ exhibiting transport phenomena of Weyl fermions.

### Means for Solving the Problem

A material exhibiting transport phenomena of Weyl fermions according to embodiments of the present invention is composed of SrRuO₃ and has a ratio of a resistivity at 300 K to a resistivity at 4 K of 20 or greater.

A magnetoresistive element according to embodiments of the present invention include: a storage layer that is composed of a material exhibiting transport phenomena of Weyl fermions, the material being composed of SrRuO₃ and having a ratio of a resistivity at 300 K to a resistivity at 4 K of 20 or greater; and a first electrode and a second electrode that are connected to the storage layer.

### Effects of Embodiments of the Invention

As described above, according to embodiments of the present invention, the ratio of the resistivity at 300 K to the resistivity at 4 K is 20 or greater, and thus SrRuO₃ exhibiting transport phenomena of Weyl fermions can be obtained.

### BRIEF DESCRIPTION OF THE DRAWINGS

FIG. 1 is a perspective view illustrating a crystal structure of SrRuO₃.

FIG. 2 is a cross-sectional view illustrating a state in which an SrRuO₃ layer 202 is formed on a growth substrate 201 made of SrTiO₃ (001).

FIG. 3 is a photograph showing a high-angle annular dark field scanning transmission electron microscope image of the SrRuO₃ layer 202.

FIG. 4 is a characteristic diagram showing the temperature dependence of the resistivity of a SrRuO₃ thin film.

FIG. 5 is a characteristic diagram showing the magnetic field dependence of the Hall resistivity of the SrRuO₃ thin film at 2 K.

FIG. 6 is a characteristic diagram showing the change in magnetoresistivity of the SrRuO₃ thin film to which a magnetic field and an electric field are applied in parallel to each other at 2 K.

FIG. 7 is a characteristic diagram showing the change in magnetoresistivity of the SrRuO₃ thin film to which a magnetic field and an electric field are applied perpendicularly to each other at 2 K.

FIG. 8 is a characteristic diagram showing the change in magnetoresistivity of the SrRuO₃ thin film to which a magnetic field and an electric field are applied with the angle α therebetween changed over 360 degrees at 14 T.

FIG. 9 is a perspective view illustrating a configuration of a Hall element used for measuring the change in magnetoresistivity of the SrRuO₃ thin film.

FIG. 10 is a characteristic diagram showing the RRR dependence of the magnetoresistivity ratio of the SrRuO₃ thin film at 2 K and 9 T, {ρₓₓ(9 T)-ρₓₓ(O T)}/ρₓₓ(O T), when a magnetic field and an electric field are applied perpendicularly to each other.

FIG. 11 is a cross-sectional view illustrating a configuration of a magnetoresistive element according to an embodiment of the present invention.

FIG. 12 is a cross-sectional view illustrating a configuration of another magnetoresistive element according to an embodiment of the present invention.

### DETAILED DESCRIPTION OF ILLUSTRATIVE EMBODIMENTS

Hereinafter, a material exhibiting transport phenomena of Weyl fermions according to the embodiment of the present invention will be described. The material exhibiting the transport phenomena of Weyl fermions is composed of SrRuO₃ and has a ratio of the resistivity ρ at 300 K to the resistivity ρ at 4 K [residual resistivity ratio RRR≡ρ(300 K)/ρ(4 K)] of 20 or greater.

The material may have a stoichiometric composition substantially corresponding to that of SrRuO₃. For example, when the composition of each element of SrRuO₃ is within ±5% thereof, the RRR value of 20 or greater can be provided, and the transport phenomena of Weyl fermions can be consequently obtained which indicates high mobility exceeding 1000 cm²/Vs and chiral-anomaly-induced magnetoresistance involving a magnetoresistivity ratio exceeding -10%.

Furthermore, the above-mentioned material may be Sr₁₋ₓAₓRuO₃ in which a part of Sr is substituted with an alkali metal atom or an alkaline earth metal atom (A). In this case, when x<0.05, the transport phenomena of Weyl fermions can be obtained which indicates high mobility exceeding 1000 cm²/Vs and chiral-anomaly-induced magnetoresistance involving a magnetoresistivity ratio exceeding -10%.

Alternatively, the above-mentioned material may be Sr₁₋ₓAₓRu_{1-Y}B_{Y}O₃ in which a part of Ru is substituted with a transition metal atom (B). When Y<0.05, the transport phenomena of Weyl fermions can be obtained which indicates high mobility exceeding 1000 cm²/Vs and chiral-anomaly-induced magnetoresistance involving a magnetoresistivity ratio exceeding -10%.

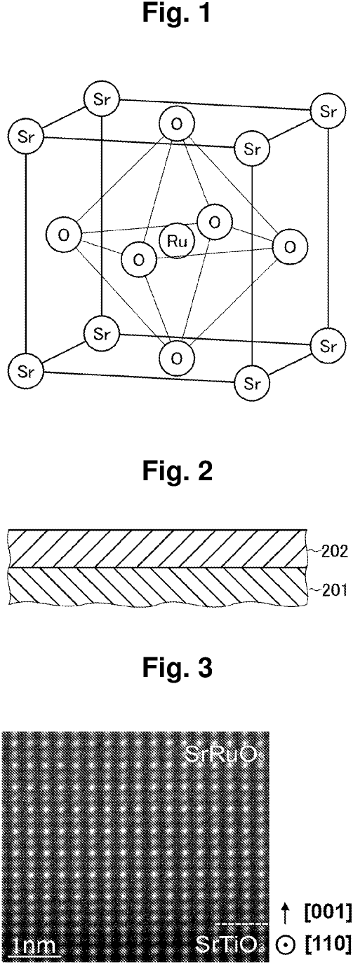

As illustrated in FIG. 1, SrRuO₃ has a cubic crystal structure in which strontium atoms Sr, ruthenium atoms Ru, and oxygen atoms O are located at lattice points. The material according to the embodiment (SrRuO₃) can provide the transport phenomena of Weyl fermions, when it is produced under the condition that the residual resistivity ratio RRR≡ρ(300 K)/ρ(4 K) (the ratio of the resistivity at 300 K, ρ(300 K), to the resistivity at 4 K, ρ(4 K)), which is one physical property value of the material, is 20 or greater. Having a perovskite structure, the material according to the embodiment is advantageous in that it can be more easily incorporated into an oxide epitaxial heterostructure as compared with a conventional material exhibiting the transport phenomena of Weyl fermions but not having a perovskite structure such as TaAs (Non-Patent Literature 6), NbP (Reference 1), and Co₃Sn₂S₂ (Reference 2).

The material exhibiting the transport phenomena of Weyl fermions according to the embodiment (SrRuO₃) can be formed as a thin film on a prescribed substrate, for example, and the thin film can be utilized. As a quality indicator of the SrRuO₃ thin film, the residual resistivity ratio RRR≡ρ(300 K)/ρ(4 K), which is the ratio of the resistivity at room temperature (300 K), ρ(300 K), to the resistivity at 4 K, ρ(4 K), is widely used.

The higher-quality SrRuO₃ thin film, which has less Ru defects and RuO₂ precipitates, can provide the smaller ρ(4 K) and the larger RRR. To allow SrRuO₃ to exhibit high mobility and chiral-anomaly-induced magnetoresistance, which are the transport properties of Weyl fermions, it is important to produce SrRuO₃ under the crystal growth condition such that the RRR value exceeds 20. With SrRuO₃ having the RRR value exceeding 20, transportation of Weyl fermions can be achieved regardless of the growth method.

An example of the growth method for the above-mentioned SrRuO₃ includes a well-known molecular beam epitaxy method. Examples of the growth method other than the molecular beam epitaxy method include sputtering and pulse laser ablation, and such methods can be used to produce SrRuO₃ capable of transporting Weyl fermions. The shape of SrRuO₃ is not limited to the thin film formed on a substrate, but may be a powder type or a bulk type obtained by a bulk synthesis technique.

Hereinafter, more detailed description is provided with experimental results.

In the experiment, a layer of SrRuO₃ was first formed. As illustrated in FIG. 2, SrRuO₃ was grown on a growth substrate 201 made of SrTiO₃ (001), which was prepared for growth, by a well-known molecular beam epitaxy method to form an SrRuO₃ layer 202 made of SrRuO₃. The growth substrate may also be composed of a material such as MgO (001) and (La_{0.3}Sr_{0.7})(Al_{0.65}Ta_{0.35})O₃ (001).

In the formation of the SrRuO₃ layer 202 by the molecular beam epitaxy, the substrate temperature was initially conditioned to 780° C. The inside of the treatment tank under an ultra-high vacuum was set to an active oxygen atmosphere at about 0.0001333 Pa (10⁻⁶ Torr). Under such a condition, atomic rays of the alkaline earth metal Sr and the 4d transition metal Ru was supplied to have a predetermined composition ratio, and SrRuO₃ was thereby grown on the growth substrate 201. The SrRuO₃ layer 202 was formed (grown) to a layer thickness of 63 nm.

The result (microscope image) through observation of the formed SrRuO₃ layer 202 with a high-angle annular dark field scanning transmission electron microscope (HAADF-STEM) will be described with reference to FIG. 3. FIG. 3 is an image obtained by projecting an electron beam into the SrRuO₃ layer 202 from the [110] direction.

FIG. 3 shows that the SrRuO₃ layer 202 is a single crystal having Sr atoms and Ru atoms arranged therein in a highly-ordered manner and having a perovskite-type structure, and grows epitaxially into a single crystal on the growth substrate 201 made of SrTiO₃.

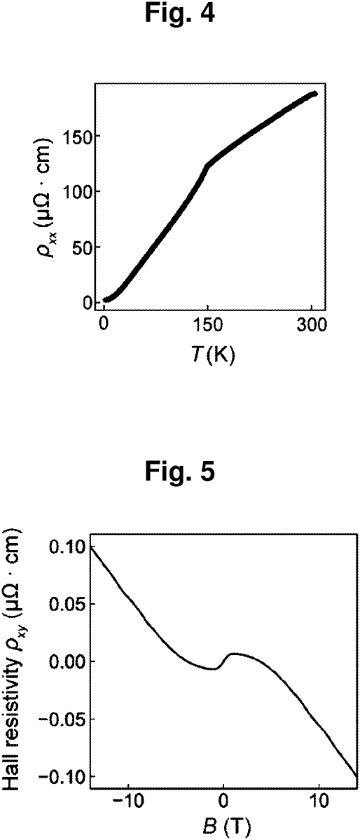

FIG. 4 shows the temperature dependence of the resistance of the SrRuO₃ thin film. The RRR value of the SrRuO₃ thin film is 81. The bending point of electrical resistance indicating the transition from paramagnetism to ferromagnetism is observed at 150 K, that is, the Curie temperature is 150 K.

FIG. 5 shows the magnetic field dependence of the Hall resistivity of the SrRuO₃ thin film at 2 K. The mobility of Weyl fermions acting as electrons is 1516 cm²/Vs, and the mobility of Weyl fermions acting as holes is 4917 cm²/Vs. Here, the mobility is estimated from fitting with a multi-carrier model to the Hall resistance.

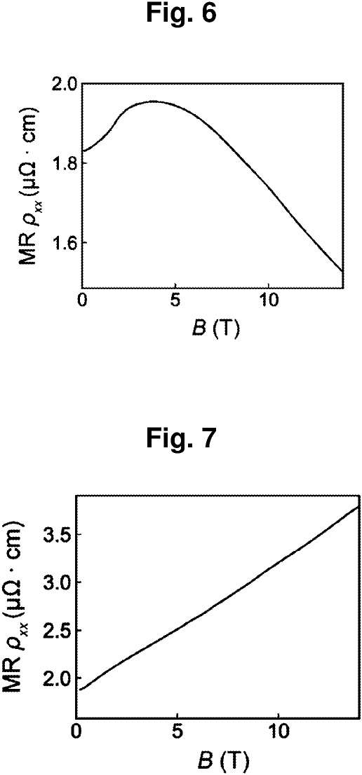

FIG. 6 shows the change in magnetoresistance of the SrRuO₃ thin film when a magnetic field and an electric field are applied in parallel to each other at 2 K. When the magnetic field value is 8 T or greater, highly linear negative magnetoresistance, that is, chiral-anomaly-induced magnetoresistance is observed, and the magnetoresistivity ratio at 14 T, {ρₓₓ(14 T)-ρₓₓ(O T)}/ρₓₓ(O T), is 16%. Here, pₓₓ(O T) represents the resistive value at o T, and ρₓₓ(14 T) represents the resistive value at 14 T. This result indicates highly linear magnetoresistance at 8 T or greater.

FIG. 7 shows the change in magnetoresistance of the SrRuO₃ thin film when a magnetic field and an electric field are applied perpendicularly to each other at 2 K. When the magnetic field value is 4 T or greater, linear positive magnetoresistance is observed, and the magnetoresistivity ratio at 14 T, {ρₓₓ(14 T)-ρₓₓ(O T)}/ρₓₓ(O T), is 108%. This result indicates that the magnetoresistance has a very good linearity.

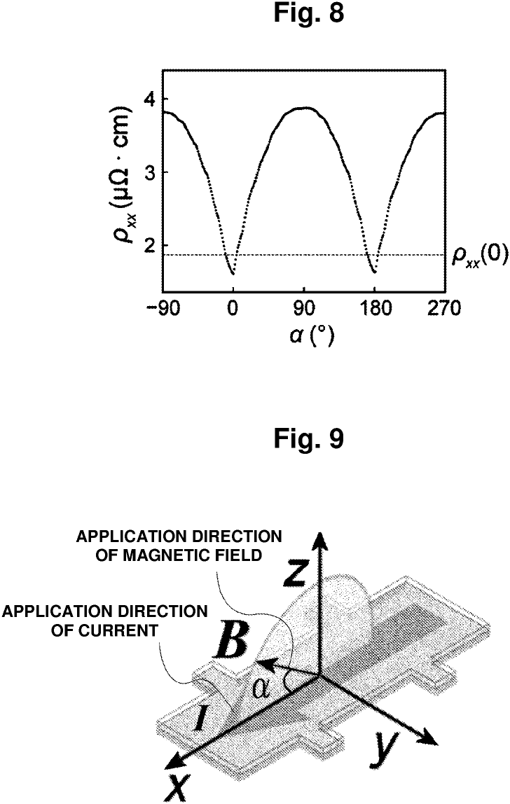

FIG. 8 shows the change in magnetoresistance of the SrRuO₃ thin film when the angle α between a magnetic field and an electric field is changed over 360 degrees at 14 T. Here, as illustrated in FIG. 9, the angle α is changed in the plane vertical to the Hall element surface. When the external magnetic field is horizontal to the current flowing through the magnetoresistive element (α=o degree or 180 degrees), the negative magnetoresistance is minimum. At this time, the magnetoresistivity ratio at 14 T, {ρₓₓ(14 T)-ρₓₓ(O T)}/ρₓₓ(O T), is -16%.

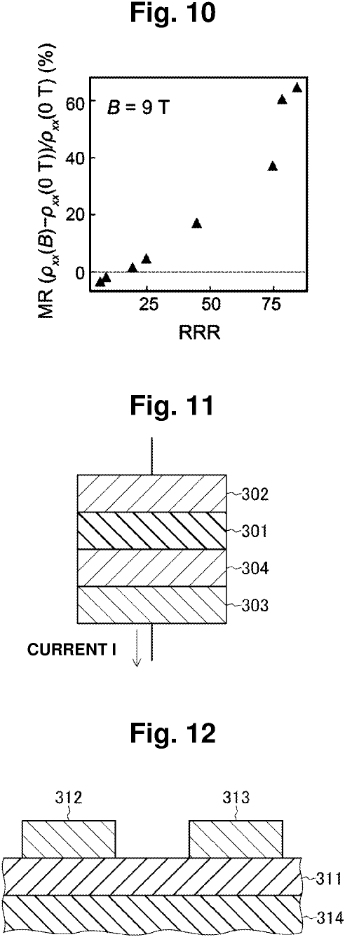

FIG. 10 shows the RRR dependence of the magnetoresistivity ratio of the SrRuO₃ thin film at 2 K and 9 T, {ρₓₓ(9 T)-ρₓₓ(O T)}/ pₓₓ(o T), when a magnetic field and an electric field are applied perpendicularly to each other. When the RRR value is 20 or greater, the positive magnetoresistance for the arrangement of the magnetic field and the electric field being parallel, which is a feature of the transport phenomena of Weyl fermions, is obtained, and this indicates that the transport phenomena of Weyl fermions are provided.

The greater RRR value leads to the greater mobility and magnetoresistivity ratio of Weyl fermions. As a result of the above-mentioned experiment, when RRR=200, high mobility exceeding 1000000 cm²/Vs, linear positive magnetoresistance exceeding 1000000%, and chiral-anomaly-induced negative magnetoresistance exceeding -100000% are obtained.

The above-mentioned example of the transport phenomena of Weyl fermions in SrRuO₃ has never been reported, and this is the first case. Embodiments of the present invention enable device applications in which the high mobility and the large positive or negative magnetoresistivity ratio of Weyl fermions are utilized.

Next, a magnetoresistive element according to an embodiment of the present invention will be described with reference to FIG. 11. The magnetoresistive element includes a storage layer 301 composed of the above-mentioned material exhibiting the transport phenomena of Weyl fermions (SrRuO₃), and a first electrode 302 and a second electrode 303 that are connected to the storage layer 301. In this example, the storage layer 301 is formed on a conductive substrate 304. The substrate 304 can be composed of Nb:SrTiO₃, for example. The first electrode 302 is formed on the storage layer 301 formed on the main surface of the substrate 304, while the second electrode 303 is formed on the rear surface of the substrate 304. Alternative configuration is possible in which a conductive layer composed of Nb:SrTiO₃ is formed on an insulating substrate, a layer of SrRuO₃ according to embodiments of the present invention is formed as a storage layer on the conductive layer, and the conductive layer is separated from the storage layer and the insulating substrate and is then interposed between the first electrode and the second electrode.

The magnetoresistive element may also have a configuration illustrated in FIG. 12. This magnetoresistive element also includes a storage layer 311 composed of the material exhibiting the transport phenomena of Weyl fermions (SrRuO₃), and a first electrode 312 and a second electrode 313 that are connected to the storage layer 311. In this example, the storage layer 311 is formed on an insulating substrate 314. The substrate 314 can be composed of SrTiO₃, for example. The first electrode 312 and the second electrode 313 are formed on the same surface of the storage layer 301 so that they are spaced apart from each other.

The resistive value of the above-mentioned magnetoresistive element changes linearly depending on the external magnetic field. When the external magnetic field is perpendicular to the current flowing through the magnetoresistive element, positive magnetoresistance (1000000% at 14 T) is observed. On the other hand, in the horizontal case, negative magnetoresistance (-100000% at 14 T) is observed. The magnetoresistivity ratio takes the minimum value when the external magnetic field and the current are completely parallel to each other. Therefore, the direction of the external magnetic field can be determined by rotating the magnetoresistive element. In this way, the magnetoresistive element can be operated as a magnetic sensor that can detect not only the magnitude of the external magnetic field but also the direction of the external magnetic field. The magnetoresistive element can be used as a memory such as an MRAM in addition to the magnetic sensor.

As described above, according to embodiments of the present invention, the ratio of the resistivity at 300 K to the resistivity at 4 K is 20 or greater, and thus SrRuO₃ exhibiting the transport phenomena of Weyl fermions can be obtained.

It is apparent that the present invention is not limited to the embodiments described above, and that many modifications and combinations can be made within the technical idea of the present invention by those having ordinary skills in the art.

Reference 1: C. Shekhar et al., “Extremely large magnetoresistance and ultrahigh mobility in the topological Weyl semimetal candidate NbP”, Nature Physics, vol. 11, pp. 645-649, 2015.

Reference 2: D. F. Liu et al., “Magnetic Weyl semimetal phase in a Kagome crystal”, Science, vol. 365, pp. 1282-1285, 2019.

### Reference Signs List

201 growth substrate

202 SrRuO₃ layer

301 storage layer

302 first electrode

303 second electrode

304 substrate

311 storage layer

312 first electrode

313 second electrode

314 substrate.

1-4. (canceled)

5. A material exhibiting transport phenomena of Weyl fermions, the material being composed of SrRuO₃ and having a ratio of a resistivity at 300 K to a resistivity at 4 K of 20 or greater.

6. The material according to claim 5, wherein the material is connected to a first electrode and a second electrode.

7. The material according to claim 5, wherein the material is disposed on a conductive substrate.

8. A magnetoresistive element comprising:
a storage layer that is composed of a material exhibiting transport phenomena of Weyl fermions, the material being composed of SrRuO₃ and having a ratio of a resistivity at 300 K to a resistivity at 4 K of 20 or greater;
a first electrode connected to the storage layer; and
a second electrode connected to the storage layer.

9. The magnetoresistive element according to claim 8, further comprising a conductive substrate on which the storage layer is disposed.

10. The magnetoresistive element according to claim 9, wherein the first electrode is disposed on a main surface of the conductive substrate, and wherein the second electrode is disposed on a rear surface of the conductive substrate.

11. The magnetoresistive element according to claim 10, wherein the storage layer is disposed between the first electrode and the main surface of the conductive substrate.

12. The magnetoresistive element according to claim 8, wherein the first electrode and the second electrode are disposed on a same surface of the storage layer and spaced apart from each other.

13. A method of forming a magnetoresistive element, the method comprising:
forming a storage layer that is composed of a material exhibiting transport phenomena of Weyl fermions, the material being composed of SrRuO₃ and having a ratio of a resistivity at 300 K to a resistivity at 4 K of 20 or greater;
forming a first electrode connected to the storage layer; and
forming a second electrode connected to the storage layer.

14. The method according to claim 13, wherein forming the storage layer comprises forming the storage layer on a conductive substrate.

15. The method according to claim 14, wherein forming the first electrode and forming the second electrode comprises:
forming the first electrode on a main surface of the conductive substrate; and
forming the second electrode on a rear surface of the conductive substrate.

16. The method according to claim 15, wherein forming the first electrode comprises forming the first electrode on the storage layer, the storage layer being disposed between the first electrode and the main surface of the conductive substrate.

17. The method according to claim 13, wherein forming the first electrode and forming the second electrode comprises forming the first electrode and the second electrode on a same surface of the storage layer and spaced apart from each other.
